(19) United States
(12) Patent Application Publication
(10) Pub. No.: US 2022/0037962 A1
(43) Pub. Date: Feb. 3, 2022

(54) CANNED MOTOR DEVICE CAPABLE OF DETECTING LEAKAGE

(71) Applicant: ZI YI ELECTRICAL ENGINEERING CO., LTD., Taichung City (TW)

(72) Inventor: Ting-Tsai Huang, Taichung City (TW)

(73) Assignee: ZI YI ELECTRICAL ENGINEERING CO., LTD., Taichung City (TW)

(21) Appl. No.: 16/983,295

(22) Filed: Aug. 3, 2020

(51) Int. Cl. H02K 9/193; G01R 31/34; G01R 31/52; H02K 9/197; H02K 11/20

(52) U.S. Cl. CPC H02K 9/193; G01R 31/34; H02K 11/20; H02K 9/197; G01R 31/52

(57) ABSTRACT

A canned motor device includes a motor unit and a sensor. The motor unit includes a rotor, a stator, and first and second casing bodies. The first casing body includes a first surrounding wall and a first side wall cooperating with the first surrounding wall to define an accommodating space for accommodating the rotor therein. The second casing body includes a second surrounding wall surrounding the first surrounding wall and a second side wall corresponding in position to the first side wall. The stator surrounds the second surrounding wall. The sensor is mounted to the second casing body and detects a leakage according to a change in electrostatic capacity between the first and second side walls.

### FIELD

The disclosure relates to a motor device, and more particularly to a canned motor device capable of detecting leakage.

### BACKGROUND

Referring to FIG. 1, a conventional magnetically driven canned motor device disclosed in Taiwanese Patent No. 1424661 includes a front cover 96, a support frame 97, an impeller 95, a cup-shaped rear cover 93, an inner rotor 92, an outer rotor 94, a fixed shaft 91 and a bracket 98. The front cover 96 has an inlet 961 and an outlet 962. The rear cover 93 is a double-layered structure, and has an inner lining 931 made of a fluoroplastic material and a reinforcing layer 932.

During operation of the conventional magnetically driven pump, a chemical fluid is introduced into the inlet 961 and guided by the impeller 95 to dissipate heat generated by the inner rotor 92 and then flows out of the outlet 962. The arrows shown in FIG. 5 indicate the directions that the chemical fluid flows.

While the inner lining 931 and the reinforcing layer 932 abut against each other to form the double-layered structure of the rear cover 93, the diameter of the reinforcing layer 932 is smaller than that of the inner lining 931. As such, if the inner lining 931 is damaged, chemical fluid may easily leak through the crack of the inner lining 931 into a gap between the inner lining 931 and the reinforcing layer 932, and then flow toward the outer rotor 94 through a periphery of the reinforced layer 932, thereby corroding the motor device.

### SUMMARY

Therefore, an object of the disclosure is to provide a canned motor device that can alleviate the drawback of the prior art.

According to the disclosure, the canned motor device includes a base unit, a motor unit and a leak detection sensor. The base unit includes a fixed seat surrounding an axis. The motor unit includes a rotor, a first casing body, a second casing body and a stator. The rotor surrounds and is rotatable about the axis. The first casing body is sleeved on the rotor, and includes a first surrounding wall, a first side wall, and a first flange wall. The first surrounding wall has two ends opposite to each other along the axis. The first side wall is connected to one of the ends of the first surrounding wall and cooperates with the first surrounding wall to define an accommodating space open at the other one of the ends of the first surrounding wall for accommodating the rotor therein. The first flange wall is connected to the other one of the ends of the first surrounding wall and extends radially and outwardly from the first surrounding wall.

The second casing body is sleeved on the first casing body, and includes a second surrounding wall, a second side wall, and a second flange wall. The second surrounding wall has two ends opposite to each other along the axis and surrounds the first surrounding wall. The second side wall is connected to one of the ends of the second surrounding wall and corresponds in position to the first side wall. The second flange wall is connected to the other one of the ends of the second surrounding wall and extends radially and outwardly from the second surrounding wall. The stator surrounds the second surrounding wall and corresponds in position to the rotor. The leak detection sensor is mounted to the second casing body and includes a sensor module configured to detect a leakage according to a change in electrostatic capacity between the second side wall and the first side wall.

### BRIEF DESCRIPTION OF THE DRAWINGS

Other features and advantages of the disclosure will become apparent in the following detailed description of the embodiments with reference to the accompanying drawings, of which:

FIG. 1 is a schematic sectional view of a conventional magnetically driven canned motor device, illustrating a chemical fluid circulating in the conventional canned motor device;

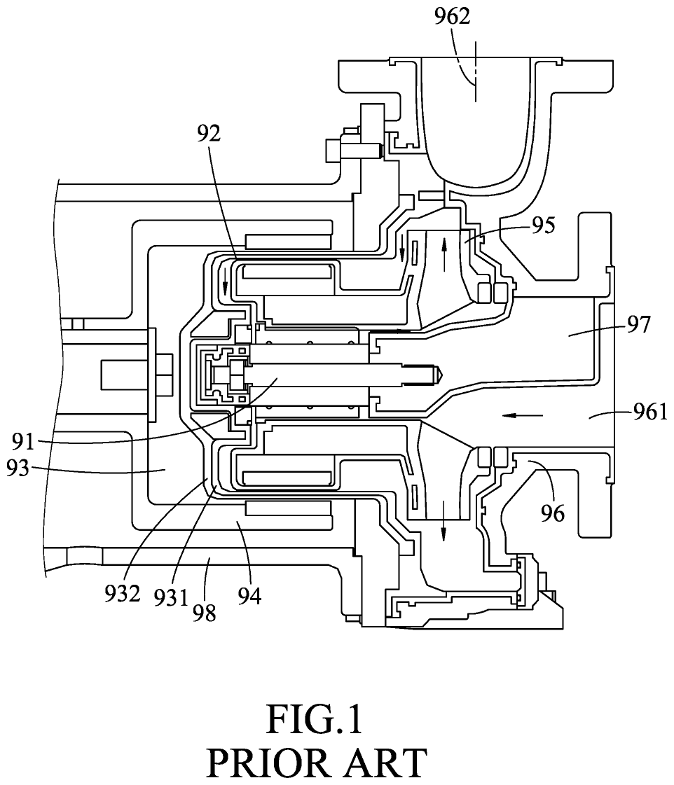

FIG. 2 is a perspective view of a first embodiment of a canned motor device according to the disclosure;

FIG. 3 is a sectional view of the first embodiment;

FIG. 4 is a fragmentary sectional view of the first embodiment;

FIG. 5 is a schematic sectional view of a second embodiment of the canned motor device according to the disclosure; and

FIG. 6 is a fragmentary sectional view of the second embodiment.

### DETAILED DESCRIPTION

Before the present disclosure is described in greater detail, it should be noted herein that like elements are denoted by the same reference numerals throughout the disclosure.

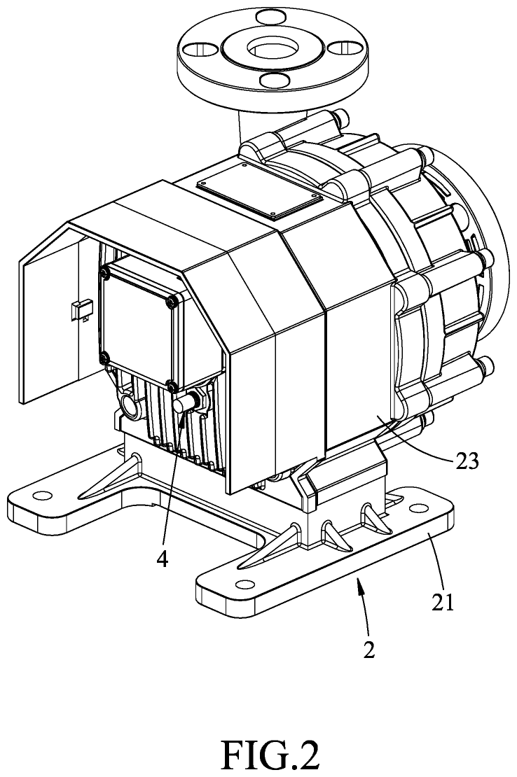

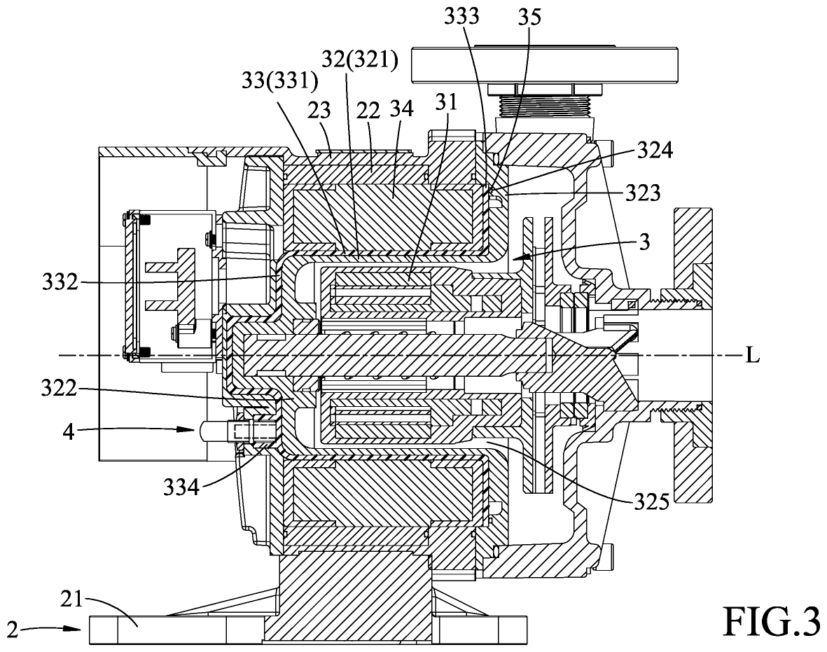

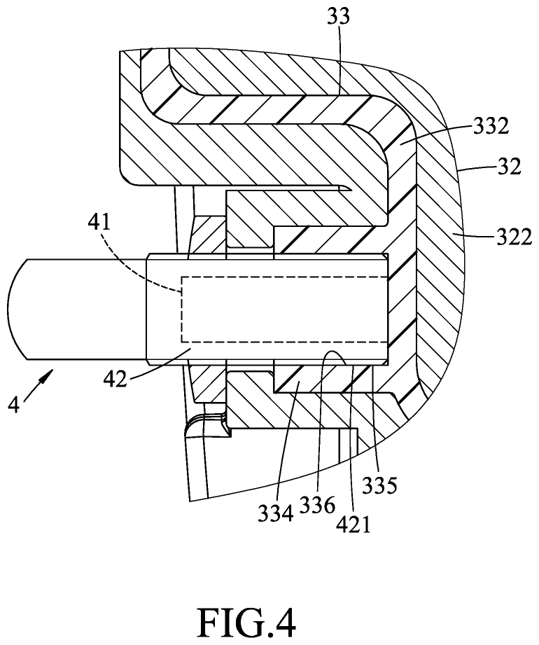

Referring to FIGS. 2 to 4, a first embodiment of a canned motor device according to the disclosure includes a base unit 2, a motor unit 3, and a leak detection sensor 4. The base unit 2 includes a base seat 21, a fixed seat 22 surrounding an axis (L), and an annular cover 23. The base seat 21 is mounted with the fixed seat 22. The annular cover 23 covers the fixed seat 22. The motor unit 3 includes a rotor 31, a first casing body 32, a second casing body 33, a stator 34 and a motor sealing ring 35.

The rotor 31 surrounds and is rotatable about the axis (L). The first casing body 32 is sleeved on the rotor 31, and includes a first surrounding wall 321, a first side wall 322, a first flange wall 323, and an annular groove 324. The first surrounding wall 321 has two ends opposite to each other along the axis (L). The first side wall 322 is connected to one of the ends of the first surrounding wall 321 and cooperates with the first surrounding wall 321 to define an accommodating space 325 open at the other one of the ends of the first surrounding wall 321 for accommodating the rotor 31 therein. The first flange wall 323 is connected to the other one of the ends of the first surrounding wall 321 and extends radially and outwardly from the first surrounding wall 321. The annular groove 324 is formed in the first flange wall 323, and surrounds the axis (L).

The second casing body 33 is sleeved on the first casing body 32, includes a second surrounding wall 331 a second side wall 332, a second flange wall 333, and a mounting tube 334. The second surrounding wall 331 has two ends opposite to each other along the axis (L) and surrounds the first surrounding wall 321. The second side wall 332 is connected to one of the ends of the second surrounding wall 331 and corresponds in position to the first side wall 322. The second flange wall 333 is connected to the other one of the ends of the second surrounding wall 331 and extends radially and outwardly from the second surrounding wall 331. The mounting tube 334 extends from the second side wall 332 away from the first side wall 322, defines amounting space 335 for mounting of the leak detection sensor 4, and is formed with an internal thread 336. The stator surrounds the second surrounding wall 331 and corresponds in position to the rotor 31.

The leak detection sensor 4 is mounted to the mounting tube 334 of the second casing body 33 and includes a sensor module 41 and a shell portion 42. The sensor module 41 is configured to detect a leakage according to a change in electrostatic capacity between the second side wall 332 and the first side wall 322. The shell portion 42 is mounted into the mounting space 335 and is formed with an external thread 421 engaging the internal thread 336. In this embodiment, the sensor module 41 is a capacitive proximity sensor that can be short-circuited or open-circuited when detecting a certain level of electrostatic capacity.

The motor sealing ring 35 is mounted between the first flange wall 323 and the second flange wall 333. Specifically, the motor sealing ring 35 is received in the annular groove 324 formed in the first flange wall 323 to form an airtight seal between the first flange wall 323 and the second flange wall 333. In this embodiment, the motor sealing ring 35 is an O-ring.

Generally, a chemical fluid is introduced into the accommodating space 325 for dissipating heat generated by the rotor 31. However, when the first casing body 32 is damaged or broken, the chemical fluid leaks out of the accommodating space 325 and damages the stator 34 of the motor unit 3.

The sensor module 41 continuously detects a leakage according to a change in electrostatic capacity between the second side wall 332 and the first side wall 322. In the case that the first casing body 32 is damaged, the chemical fluid leaking out of the accommodating space 325 would flow into a space between the first side wall 322 and the second side wall 332. Thus, the electrostatic capacity detected by the sensor module 41 is changed. At this time, in one embodiment, an alert device (not shown) connected to the sensor module 41 outputs an alert signal such as light, sound, etc. to notify the user that the first casing body 32 is damaged. In other embodiments, the motor unit 3 is shut down once the sensor module 41 detects change of electrostatic capacity. By this way, damage to the stator 34 of the motor unit 3 can be prevented and a severe safety problem can also be avoided.

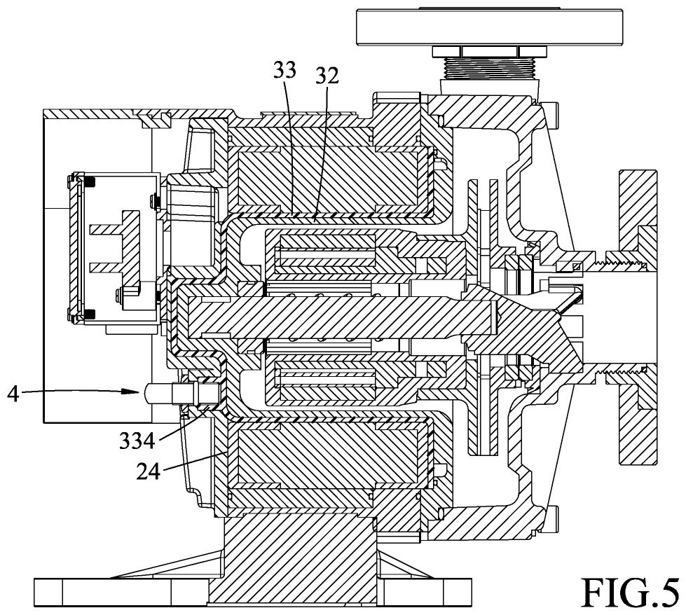

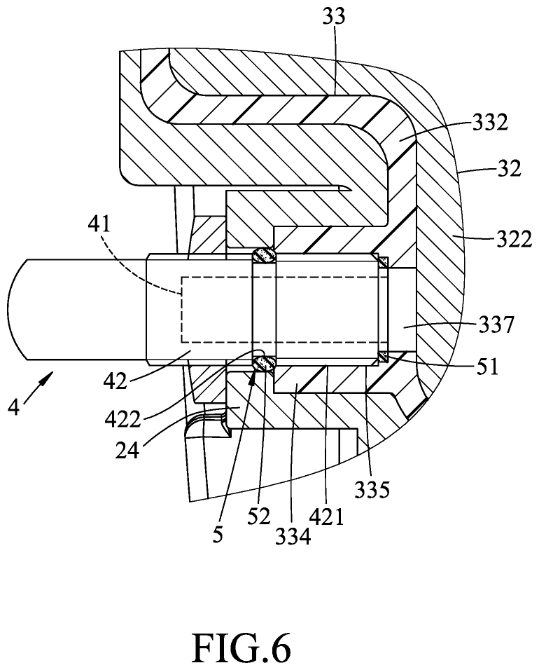

Referring to FIGS. 5 and 6, a second embodiment of the canned motor device according to the disclosure is similar to the first embodiment and the difference between the first and the second embodiment resides in the following. In the second embodiment, the second casing body 33 has a through hole 337 formed through the second side wall 332 and in spatial communication with the mounting space 335 defined by the mounting tube 334. The canned motor device of the second embodiment further includes a sealing unit 5 including a first sealing ring 51 and a second sealing ring 52.

The first sealing ring 51 abuts against the second side wall 332 and one end of the shell portion 42 of the leak detection sensor 4 that extends into the mounting space 335, and is disposed around the through hole 337 to form an airtight seal between the second casing body 33 and the shell portion 42. In the case that the first casing body 32 is damaged, the chemical fluid leaking out of the accommodating space 325 flows into a space between the first and second side walls 322, 332 and through the through hole 337 to contact the sensor module 41. Then, the sensor module 41 detects a leakage according to a change in the electrostatic capacity for subsequent procedures. The first sealing ring 51 serves as the first line of defense to prevent the chemical fluid from leaking out of the second casing body 33 and thus preventing damage to the stator 34.

Additionally, in the second embodiment, the base unit 2 further includes a lid member 24 disposed adjacent to the first and second side walls 322, 332 and covering the second side wall 332 and the second mounting tube 334. The shell portion 42 of the leak detection sensor 4 includes a non-threaded mounting surface 422 which is connected to an end of the external thread 421 distal from the second side wall 332, which defines an annular groove, and on which the second sealing ring 52 is sleeved. The second sealing ring 52 is sleeved on the non-threaded mounting surface 422 and abuts against the mounting tube 334 and the lid member 24, so as to form an airtight seal among the mounting tube 334, the lid member 24, and the shell portion 42. The second sealing ring 52 serves as a second line of defense to prevent the chemical fluid from leaking out of the accommodating space 325. In this embodiment, the first and second sealing rings 51, 52 are both O-rings. In this way, the second embodiment possesses the advantage of the first embodiment.

To sum up, by virtue of the present disclosure, in the case that the first casing body 32 is damaged or broken and the chemical fluid flows out of the accommodating space 325, the leak detection sensor 4 is capable of detecting leakage of the chemical fluid to thereby prevent damage to the stator 34 of the motor unit 3.

In the description above, for the purposes of explanation, numerous specific details have been set forth in order to provide a thorough understanding of the embodiment. It will be apparent, however, to one skilled in the art, that one or more other embodiments maybe practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what is considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A canned motor device comprising:
a base unit including a fixed seat surrounding an axis;
a motor unit including
a rotor surrounding and rotatable about the axis,
a first casing body sleeved on said rotor, and including a first surrounding wall that has two ends opposite to each other along the axis, a first side wall that is connected to one of said ends of said first surrounding wall and that cooperates with said first surrounding wall to define an accommodating space open at the other one of said ends of said first surrounding wall for accommodating said rotor therein, and a first flange wall that is connected to said other one of said ends of said first surrounding wall and that extends radially and outwardly from said first surrounding wall,
a second casing body sleeved on said first casing body, including a second surrounding wall that has two ends opposite to each other along the axis and that surrounds said first surrounding wall, a second side wall that is connected to one of said ends of said second surrounding wall and that corresponds in position to said first side wall, and a second flange wall that is connected to the other one of said ends of said second surrounding wall and that extends radially and outwardly from said second surrounding wall, and
a stator surrounding said second surrounding wall and corresponding in position to said rotor; and
a leak detection sensor mounted to said second casing body and including a sensor module configured to detect a leakage according to a change in electrostatic capacity between said second side wall and said first side wall.

2. The canned motor device as claimed in claim 1, wherein said second casing body includes a mounting tube extending from said second side wall away from said first side wall and defining a mounting space for mounting of said leak detection sensor.

3. The canned motor device as claimed in claim 2, wherein said mounting tube is formed with an internal thread, said leak detection sensor further including a shell portion mounted into said mounting space and formed with an external thread engaging said internal thread.

4. The canned motor device as claimed in claim 3, wherein said second casing body has a through hole formed through said second side wall and in spatial communication with said mounting space defined by said mounting tube.

5. The canned motor device as claimed in claim 4, further comprising a sealing unit including a first sealing ring abutting against said second side wall and one end of said shell portion that extends into said mounting space, and disposed around said through hole to form an airtight seal between said second casing body and said shell portion.

6. The canned motor device as claimed in claim 5, wherein said base unit further includes a lid member covering said second side wall and the mounting tube, said sealing unit further including a second sealing ring sleeved on said shell portion and abutting against said mounting tube and said lid member, so as to form an airtight seal among said mounting tube, said pressing member, and said shell portion.

7. The canned motor device as claimed in claim 6, wherein said shell portion includes a non-threaded mounting surface which is connected to an end of said external thread distal from said second side wall, which defines an annular groove, and on which said second sealing ring is sleeved.

8. The canned motor device as claimed in claim 1, wherein said motor unit further includes a motor sealing ring mounted between said first flange wall and said second flange wall, said first casing body having an annular groove formed in said first flange wall, surrounding said axis, and receiving said motor sealing ring to form an airtight seal between said first flange wall and said second flange wall.

9. The canned motor device as claimed in claim 1, wherein said base unit further includes a base seat mounted with said fixed seat, and an annular cover covering said fixed seat.
